(19) United States
(12) Patent Application Publication
(10) Pub. No.: US 2014/0291872 A1
(43) Pub. Date: Oct. 2, 2014

(54) Gel Having Improved Thermal Stability

(71) Applicant: Dow Corning Corporation, Midland, MI (US)

(72) Inventors: Brian R. Harkness, Midland, MI (US); Malinda N. Howell, Freeland, MI (US); Daesup Hyun, Kyunggido (KR); Jing Jiang, Midland, MI (US); John J. Kennan, Midland, MI (US); Kent R. Larson, Midland, MI (US); Randall G. Schmidt, Midland, MI (US); Shengqing Xu, Midland, MI (US)

(21) Appl. No.: 14/349,383

(22) PCT Filed: Oct. 5, 2012
(86) PCT No.: PCT/US2012/058974

§ 371 Date: Apr. 3, 2014

Related U.S. Application Data
(60) Provisional application No. 61/543,990, filed on Oct. 6, 2011.

(51) Int. Cl. C08G 77/38; H01L 23/29; C08J 3/28

(52) U.S. Cl. CPC C08G 77/38; C08J 3/28; H01L 23/296
USPC 257/791; 165/185; 528/15; 522/66

(57) ABSTRACT

A gel has improved thermal stability and is the ultraviolet hydrosilylation reaction product of (A) an organopolysiloxane having an average of at least 0.1 silicon-bonded alkenyl group per molecule and (B) a cross-linker having an average of at least 2 silicon-bonded hydrogen atoms per molecule. (A) and (B) react via hydrosilylation in the presence of (C) a UV-activated hydrosilylation catalyst comprising at least one of platinum, rhodium, ruthenium, palladium, osmium, and iridium, and (D) a thermal stabilizer. The (D) thermal stabilizer is present in an amount of from about 0.01 to about 30 weight percent based on a total weight of (A) and (B) and having transparency to UV light sufficient for the ultraviolet hydrosilylation reaction product to form.

### FIELD OF THE DISCLOSURE

The present disclosure generally relates to a gel that is an ultraviolet hydrosilylation reaction product having improved thermal stability.

### DESCRIPTION OF THE RELATED ART

Typical silicones have excellent stress-buffering properties, electrical properties, resistance to heat, and weather-proof properties and can be used in many applications. In many applications, silicones can be used to transfer heat away from heat-generating electronic components. However, when used in high performance electronic articles that include electrodes and small electrical wires, typical silicones tend to harden, become brittle, and crack, after exposure to long operating cycles and high heat. The hardening and cracking disrupt or destroy the electrodes and wires thereby causing electrical failure. Accordingly, there remains an opportunity to develop an improved silicone.

### SUMMARY OF THE DISCLOSURE AND ADVANTAGES

The instant disclosure provides a gel that has improved thermal stability. The gel is the ultraviolet hydrosilylation reaction product of (A) an organopolysiloxane having an average of at least 0.1 silicon-bonded alkenyl group per molecule and (B) a cross-linker having an average of at least 2 silicon-bonded hydrogen atoms per molecule. (A) and (B) react via hydrosilylation in the presence of (C) a ultraviolet (UV)-activated hydrosilylation catalyst comprising at least one of platinum, rhodium, ruthenium, palladium, osmium, and iridium, and (D) a thermal stabilizer. The (D) thermal stabilizer is present in an amount of from about 0.01 to about 30 weight percent based on a total weight of (A) and (B) and has transparency to UV light sufficient for the ultraviolet hydrosilylation reaction product to form.

The (C) UV-activated hydrosilylation catalyst allows the gel to form (i.e., allows (A) and (B) to react) without the use of heat which reduces production times, costs, and complexities. The (D) thermal stabilizer does not prevent the UV light from penetrating the gel and simultaneously allows the gel to maintain a low Young's modulus (i.e., low hardness and viscosity) properties even after extensive heat ageing. Young's modulus is referred to herein below simply as “modulus.” A gel that has low modulus is less prone to hardening, becoming brittle, and cracking, after exposure to long operating cycles and high heat, decreasing the chance that, when used in an electronic article, any electrodes or wires will be damaged, thereby decreasing the chance that electrical failure will occur.

### BRIEF DESCRIPTION OF THE DRAWINGS

Other advantages of the present disclosure will be readily appreciated, as the same becomes better understood by reference to the following detailed description when considered in connection with the accompanying drawings.

FIG. 1 is a UV/Vis spectrogram of three different solutions of ferrocenes (i.e., butyroferrocene, ethylferrocene, and butylferrocene) in cyclohexane. FIG. 1 shows that butyroferrocene absorbs UV light between 300 and 400 nanometers.

FIG. 2 is a UV/Vis spectrogram of three different solutions of cyclohexane. The first solution is cyclohexane alone. The second and third solutions include the cyclohexane and methylcyclopentadienyl trimethylplatinum (one example of a UV-activated hydrosilylation catalyst) dissolved in the cyclohexane in two different concentrations (10 ppm and 20 ppm). FIG. 2 shows that methylcyclopentadienyl trimethylplatinum catalyst also absorbs UV light between 300 and 400 nanometers.

FIG. 3 is an overlay of the UV/Vis spectra of FIGS. 1 and 2. FIG. 3 shows that there is overlap in the UV absorbance of the butyroferrocene set forth in FIG. 1 and the UV absorbance of the methylcyclopentadienyl trimethylplatinum catalyst set forth in FIG. 2.

### DETAILED DESCRIPTION OF THE DISCLOSURE

The “Summary of the Disclosure and Advantage” and Abstract are incorporated here by reference.

The terminology “ultraviolet hydrosilylation reaction product” describes that (A) and (B) react in a hydrosilylation reaction in the presence of (C) and (D) using ultraviolet light to promote, accelerate, or initiate reaction of (A) and (B). Typically, (A) and (B) react such that the gel forms and cures, either partially or completely.

### (A) Organopolysiloxane:

The (A) organopolysiloxane may be a single polymer or may include two or more polymers that differ in at least one of the following properties: structure, average molecular weight, siloxane units, and sequence, and viscosity due to the difference in these properties. The (A) organopolysiloxane has an average of at least 0.1 silicon-bonded alkenyl group per individual polymer molecule, i.e., there is, on average, at least one silicon-bonded alkenyl group per 10 individual polymer molecules. More typically, the (A) organopolysiloxane has an average of 1 or more silicon-bonded alkenyl groups per molecule. In various embodiments, the (A) organopolysiloxane has an average of at least 2 silicon-bonded alkenyl groups per molecule. The (A) organopolysiloxane may have a molecular structure that is in linear form or branched linear form or in dendrite form. The (A) organopolysiloxane may be or include a single polymer, a copolymer, or a combination of two or more polymers. The (A) organopolysiloxane may be an organoalkylpolysiloxane.

The silicon-bonded alkenyl groups of the (A) organopolysiloxane are not particularly limited but typically are one or more of vinyl, allyl, butenyl, pentenyl, hexenyl, or heptenyl groups. Each alkenyl group may be the same or different and each may be independently selected from all others. Each alkenyl group may be terminal or pendant. It one embodiment, the (A) organopolysiloxane includes both terminal and pendant alkenyl groups.

The (A) organopolysiloxane may also include silicon-bonded organic groups including, but not limited to, monovalent organic groups free of aliphatic unsaturation. These monovalent organic groups may have at least one and as many as 2, 3, 4, 5, 6, 7, 8, 9, 10, 11, 12, 14, 16, 18, and 20 carbon atoms, and are exemplified by, but not limited to, alkyl groups such as methyl, ethyl, and isomers of propyl, butyl, t-butyl, pentyl, hexyl, heptyl, octyl, nonyl, decyl, undecyl, dodecyl, tetradecyl, hexadecyl, octadecyl, and eicosanyl; cycloalkyl groups such as cyclopentyl and cyclohexyl; and aromatic (i.e., aryl) groups such as phenyl, tolyl, xylyl, benzyl, and 2-phenylethyl; and 3,3,3,-trifluoropropyl, and similar halogenated alkyl groups. In certain embodiments, the organic groups are methyl or phenyl groups.

The (A) organopolysiloxane may also include terminal groups that may be further defined as alkyl or aryl groups as described above, and/or alkoxy groups exemplified by methoxy, ethoxy, or propoxy groups, or hydroxyl groups.

In various embodiments, the (A) organopolysiloxane may have one of the following formulae:

R¹₂R²SiO(R¹₂SiO)_{d}(R¹R²SiO)ₑSiR¹₂R², Formula (I):

R¹₃SiO(R¹₂SiO)_{f}(R¹R²SiO)_{g}SiR¹₃, Formula (II): or
combinations thereof.

In formulae (I) and (II), each R¹ is independently a monovalent organic group free of aliphatic unsaturation and each R² is independently an aliphatically unsaturated organic group. Suitable monovalent organic groups of R¹ include, but are not limited to, alkyl groups having 1 to 20, 1 to 15, 1 to 10, 5 to 20, 5 to 15, or 5 to 10 carbon atoms, e.g. methyl, ethyl, and isomers of propyl, butyl, t-butyl, pentyl, octyl, undecyl, and octadecyl; cycloalkyl groups such as cyclopentyl and cyclohexyl; and aryl groups such as phenyl, tolyl, xylyl, benzyl, and 2-phenylethyl. Each R² is independently an aliphatically unsaturated monovalent organic group, exemplified by alkenyl groups such as vinyl, allyl, butenyl, pentenyl, hexenyl, or heptenyl groups. It is also contemplated that R² may include halogen atoms or halogen groups.

Subscript “d” typically has an average value of at least 0.1, more typically of at least 0.5, still more typically of at least 0.8, and most typically, of at least 2. Alternatively subscript “d” may have an average value ranging from 0.1 to 2000. Subscript “e” may be 0 or a positive number. Further, subscript “e” may have an average value ranging from 0 to 2000. Subscript “f” may be 0 or a positive number. Further, subscript “f” may have an average value ranging from 0 to 2000. Subscript “g” has an average value of at least 0.1, typically at least 0.5, more typically at least 0.8, and most typically, at least 2. Alternatively, subscript “g” may have an average value ranging from 0.1 to 2000.

In various embodiments, the (A) organopolysiloxane is further defined as an alkenyldialkylsilyl end-blocked polydialkylsiloxane which may itself be further defined as vinyldimethylsilyl end-blocked polydimethylsiloxane. The (A) organopolysiloxane may be further defined as a dimethylpolysiloxane capped at one or both molecular terminals with dimethylvinylsiloxy groups; a dimethylpolysiloxane capped at one or both molecular terminals with methylphenylvinylsiloxy groups; a copolymer of a methylphenylsiloxane and a dimethylsiloxane capped at both one or both molecular terminals with dimethylvinylsiloxy groups; a copolymer of diphenylsiloxane and dimethylsiloxane capped at one or both molecular terminals with dimethylvinylsiloxy groups, a copolymer of a methylvinylsiloxane and a dimethylsiloxane capped at one or both molecular terminals with dimethylvinylsiloxy groups; a copolymer of a methylvinylsiloxane and a dimethylsiloxane capped at one or both molecular terminals with dimethylvinylsiloxy groups; a methyl (3,3,3-trifluoropropyl)polysiloxane capped at one or both molecular terminals with dimethylvinylsiloxy groups; a copolymer of a methyl(3,3,3-trifluoropropyl)siloxane and a dimethylsiloxane capped at one or both molecular terminals with dimethylvinylsiloxy groups; a copolymer of a methylvinylsiloxane and a dimethylsiloxane capped at one or both molecular terminals with silanol groups; a copolymer of a methylvinylsiloxane, a methylphenylsiloxane, and a dimethylsiloxane capped at one or both molecular terminals with silanol groups; or an organosiloxane copolymer composed of siloxane units represented by the following formulae: (CH₃)₃SiO_{1/2}, (CH₃)₂(CH₂═CH)SiO_{1/2}, CH₃SiO_{3/2}, (CH₃)₂SiO_{2/2}, CH₃PhSiO_{2/2} and Ph₂SiO_{2/2}.

The (A) organopolysiloxane may further include a resin such as an MQ resin defined as including, consisting essentially of, or consisting of R^{x}₃SiO_{1/2} units and SiO_{4/2} units, a TD resin defined as including, consisting essentially of, or consisting of R^{x}SiO_{3/2} units and R^{x}₂SiO_{2/2} units, an MT resin defined as including, consisting essentially of, or consisting of R^{x}₃SiO_{1/2} units and R^{x}SiO_{3/2} units, an MTD resin defined as including, consisting essentially of, or consisting of R^{x}₃SiO_{1/2} units, R^{x}SiO_{3/2} units, and R^{x}₂SiO_{2/2} units, or a combination thereof. R^{x} designates any monovalent organic group, for example but is not limited to, monovalent hydrocarbon groups and monovalent halogenated hydrocarbon groups. Monovalent hydrocarbon groups include, but are not limited to, alkyl groups having 1 to 20, 1 to 15, 1 to 10, 5 to 20, 5 to 15, or 5 to 10 carbon atoms, e.g. methyl, ethyl, and isomers of propyl, butyl, t-butyl, pentyl, octyl, undecyl, and octadecyl; cycloalkyl groups such as cyclohexyl; alkenyl groups such as vinyl, allyl, butenyl, and hexenyl; alkynyl groups such as ethynyl, propynyl, and butynyl; and aryl groups such as phenyl, tolyl, xylyl, benzyl, and 2-phenylethyl. In one embodiment, the (A) organopolysiloxane is free of halogen atoms. In another embodiment, the (A) organopolysiloxane includes one or more halogen atoms.

### (B) Cross-Linker:

The (B) cross-linker has an average of at least 2 silicon-bonded hydrogen atoms per molecule and may be further defined as, or include, a silane or a siloxane, such as a polyorganosiloxane. In various embodiments, the (B) cross-linker may include more than 2, 3, or even more than 3, silicon-bonded hydrogen atoms per molecule. The (B) cross-linker may have a linear, branched, or partially branched linear, cyclic, dendrite, or resinous molecular structure. The silicon-bonded hydrogen atoms may be terminal or pendant. Alternatively, the (B) cross-linker may include both terminal and pendant silicon-bonded hydrogen atoms.

In addition to the silicon-bonded hydrogen atoms, the (B) cross-linker may also include monovalent hydrocarbon groups which do not contain unsaturated aliphatic bonds, such as methyl, ethyl, and isomers of propyl, butyl, t-butyl, pentyl, hexyl, heptyl, octyl, decyl, undecyl, dodecyl, or similar alkyl groups, e.g. alkyl groups having 1 to 20, 1 to 15, 1 to 10, 5 to 20, 5 to 15, or 5 to 10 carbon atoms; cyclopentyl, cyclohexyl, or similar cycloalkyl groups; phenyl, tolyl, xylyl, or similar aryl groups; benzyl, phenethyl, or similar aralkyl groups; or 3,3,3-trifluoropropyl, 3-chloropropyl, or similar halogenated alkyl group. Preferable are alkyl and aryl groups, in particular, methyl and phenyl groups.

The (B) cross-linker may also include siloxane units including, but not limited to, HR³₂SiO_{1/2}, R³₃SiO1/2, HR³SiO_{2/2}, R³₂SiO_{2/2}, R³SiO_{3/2}, and SiO_{4/2} units. In the preceding formulae, each R³ is independently selected from monovalent organic groups free of aliphatic unsaturation. In various embodiments, the (B) cross-linker includes or is a compound of the formulae:

R³₃SiO(R³₂SiO)ₕ(R³HSiO)ᵢSiR³₃, Formula (III)

R³₂HSiO(R³₂SiO)j(R³HSiO)kSiR³₂H, Formula (IV)
or a combination thereof.

In formulae (III) and (IV) above, subscript “h” has an average value ranging from 0 to 2000, subscript “i” has an average value ranging from 2 to 2000, subscript “j” has an average value ranging from 0 to 2000, and subscript “k” has an average value ranging from 0 to 2000. Each R³ is independently a monovalent organic group. Suitable monovalent organic groups include alkyl groups having 1 to 20, 1 to 15, 1 to 10, 5 to 20, 5 to 15, or 5 to 10 carbon atoms, e.g. methyl, ethyl, and isomers of propyl, butyl, t-butyl, pentyl, octyl, decyl, undecyl, dodecyl, and octadecyl; cycloalkyl such as cyclopentyl and cyclohexyl; alkenyl such as vinyl, allyl, butenyl, and hexenyl; alkynyl such as ethynyl, propynyl, and butynyl; and aryl such as phenyl, tolyl, xylyl, benzyl, and 2-phenylethyl.

The (B) cross-linker may alternatively be further defined as a methylhydrogen polysiloxane capped at both molecular terminals with trimethylsiloxy groups; a copolymer of a methylhydrogensiloxane and a dimethylsiloxane capped at both molecular terminals with trimethylsiloxy groups; a dimethylpolysiloxane capped at both molecular terminals with dimethylhydrogensiloxy groups; a methylhydrogenpolysiloxane capped at both molecular terminals with dimethylhydrogensiloxy groups; a copolymer of a methylhydrogensiloxane and a dimethylsiloxane capped at one or both molecular terminals with dimethylhydrogensiloxy groups; a cyclic methylhydrogenpolysiloxane; and/or an organosiloxane composed of siloxane units represented by the following formulae: (CH₃)₃SiO_{1/2}, (CH₃)₂HSiO_{1/2}, and SiO_{4/2}; tetra(dimethylhydrogensiloxy) silane, or methyl-tri(dimethylhydrogensiloxy)silane.

It is also contemplated that the (B) cross-linker may be or include a combination of two or more organohydrogenpolysiloxanes that differ in at least one of the following properties: structure, average molecular weight, viscosity, siloxane units, and sequence. The (B) cross-linker may also include a silane. Dimethylhydrogensiloxy-terminated poly dimethylsiloxanes having relatively low degrees of polymerization (DP) (e.g., DP ranging from 3 to 50) are commonly referred to as chain extenders, and a portion of the (B) cross-linker may be or include a chain extender. In one embodiment, the (B) cross-linker is free of halogen atoms. In another embodiment, the (B) cross-linker includes one or more halogen atoms per molecule. It is contemplated that the gel, as a whole, may be free of halogen atoms or may include halogen atoms.

### (C) UV-Activated Hydrosilylation Catalyst:

The (C) UV-activated hydrosilylation catalyst includes at least one of platinum, rhodium, ruthenium, palladium, osmium, and iridium. It is contemplated that more than one metal may be utilized in the (C) UV-activated hydrosilylation catalyst or that more than one (C) UV-activated hydrosilylation catalyst may be utilized in this disclosure. The terminology “UV-activated” describes that the catalyst tends to respond to ultraviolet light (i.e., light at a wavelength of from 150 to 450 nm) and typically changes structure and/or activity when exposed to the ultraviolet light. For example, the catalyst may have a first structure before exposure to ultraviolet light and then a second structure that is different from the first structure, after exposure to the ultraviolet light. As a further example, the structures may change relative to ligand size, ligand orientation, oxidation, etc. It is contemplated that the (C) UV-activated hydrosilylation catalyst may be alternatively described as UV-accelerated and/or UV-promoted, since some catalysts may exhibit minimal activity with heating but typically do not exhibit significant activity until exposed to UV light. The (C) UV-activated hydrosilylation catalyst may be utilized in this disclosure before exposure to ultraviolet light or after exposure to ultraviolet light. Alternatively, the same catalyst may be used in more than one portion, e.g., wherein a first portion (or amount) of the catalyst is exposed to ultraviolet light and thus has a first structure and a second portion (or amount) of the same catalyst is not exposed to ultraviolet light (prior to use) and thus has a second structure. Both the first and second portions may be simultaneously utilized to form the gel. It is also contemplated that the (C) UV-activated hydrosilylation catalyst may be activated by, or exposed to, UV light before any exposure of (A), (B), (D), (E) and/or any optional additives to UV light. Said differently, (C) may be exposed to UV light independently before any combination with (A), (B), (D), (E) and/or any optional additives.

Non-limiting examples of the (C) UV-activated hydrosilylation catalyst include platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3 -butanedioate, platinum(II) bis(1,3-diphenyl-1,3-propanedioate), platinum(II) bis(1,1,1, 5,5,5-hexafluoro-2,4-pentanedioate); (n-cyclopentadienyl)trialkylplatinum complexes, such as (Cp)trimethylplatinum, (methylCp)trimethylplatinum, (ethylCp)trimethylplatinum, (propylCp)trimethylplatinum (butylCp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl; triazene oxide-transition metal complexes, such as Pt[C₆H₅NNNOCH₃]₄, Pt[p-CN—C₆H₄NNNOC₆H₁₁]₄, Pt[p-H₃COC₆H₄NNNOC₆H¹¹[₄, Pt[p-CH₃(CH₂)ₓ—C₆H₄NNNOCH₃]₄, 1,5-cyclooctadienePt[p-CN—C₆H₄NNNOC₆H₁₁]₂, 1,5-cyclooctadiene.Pt[p-CH₃O—C₆H₄NNNOCH₃]₂, [(C₆H₅)₃P]₃Rh[p-CN—C₆H₄NNNOC₆H₁₁], and Pd[p-CH₃(CH₂)ₓ—C₆H₄NNNOCH₃]₂, where x is 1, 3, 5, 11, or 17; (η-diolefin)(σ-aryl)platinum complexes, such as (η₄-1,5-cyclooctadienyl)diphenylplatinum, (η⁴-1,3,5,7-cyclooctatetraenyl)diphenylplatinum, (η⁴-2,5-norboradienyl)diphenylplatinum, (η⁴-1,5-cyclooctadienyl)bis-(4-dimethylaminophenyl)platinum, (η₄-1,5-cyclooctadienyl)bis-(4-acetylphenyl)platinum, and (η⁴-1,5-cyclooctadienyl)bis-(4-trifluormethylphenyl)platinum, and combinations thereof. In one embodiment, the (C) UV-activated hydrosilylation catalyst is further defined as (η-cyclopentadienyl) trialkylplatinum complex. In one embodiment, the (C) UV-activated hydrosilylation catalyst is further defined as methylcyclopentadienyl trimethylplatinum. It is also contemplated that rhodium, ruthenium, palladium, osmium, and iridium analogs of one or more of the aforementioned compounds may also be utilized. In other non-limiting embodiments, the (C) UV-activated hydrosilylation catalyst may be as described in one or more of U.S. Pat. Nos. 4,510,094, 4,530,879, 6,150,546, and 6,376,569, each of which is expressly incorporated herein by reference. The (C) UV-activated hydrosilylation catalyst is not particularly limited relative to concentration but is typically present in amounts of from 0.01 to 1000 ppm, 0.1 to 1000 ppm, 0.01 to 500 ppm, 0.1 to 500 ppm, from 0.5 to 100 ppm, or from 1 to 25 ppm, based on the total weight of (A), (B), and (C).

### (D) Thermal Stabilizer:

The (D) thermal stabilizer of this disclosure is not particularly limited except that the (D) thermal stabilizer has transparency to UV light sufficient for the ultraviolet hydrosilylation reaction product to form. The terminology “sufficient” is well understood and appreciated by those of skill in the art. This terminology describes that a certain amount of UV light must reach the (C) UV-activated hydrosilylation catalyst to activate (C) which, in turns, catalyzes the hydrosilylation reaction of (A) and (B) to such a degree that the gel, i.e., the ultraviolet hydrosilylation reaction product, forms. The sufficiency of the transparency is not particularly limited and, as understood by those of skill in the art, may change depending on choice of (A), (B), (C), and even (E), as described in detail below.

Most preferably, the chosen (D) thermal stabilizer does not block or absorb significant amounts of UV light at the same wavelengths as is absorbed by the chosen (C) UV-activated hydrosilylation catalyst. Again, the terminology “significant” is not necessarily quantified in the same way across all chemistries. It may change depending on choice of (A), (B), (C), and (E). Said differently, the (D) thermal stabilizer must not prevent (e.g. must allow) a sufficient amount of UV light to react and activate the (C) UV-activated catalyst. If the (D) thermal stabilizer does not allow a sufficient amount of UV light to penetrate, the (C) catalyst will not be sufficiently activated and (A) and (B) will not react to form the gel of this disclosure. More specifically, in this scenario, no appreciable hydrosilylation reaction will occur. For example, if an insufficient amount of UV light reaches (C), then insignificant portions of (A) and (B) may react but such little reaction will not produce the gel of this disclosure. Instead, whatever product is produced, would not be a gel.

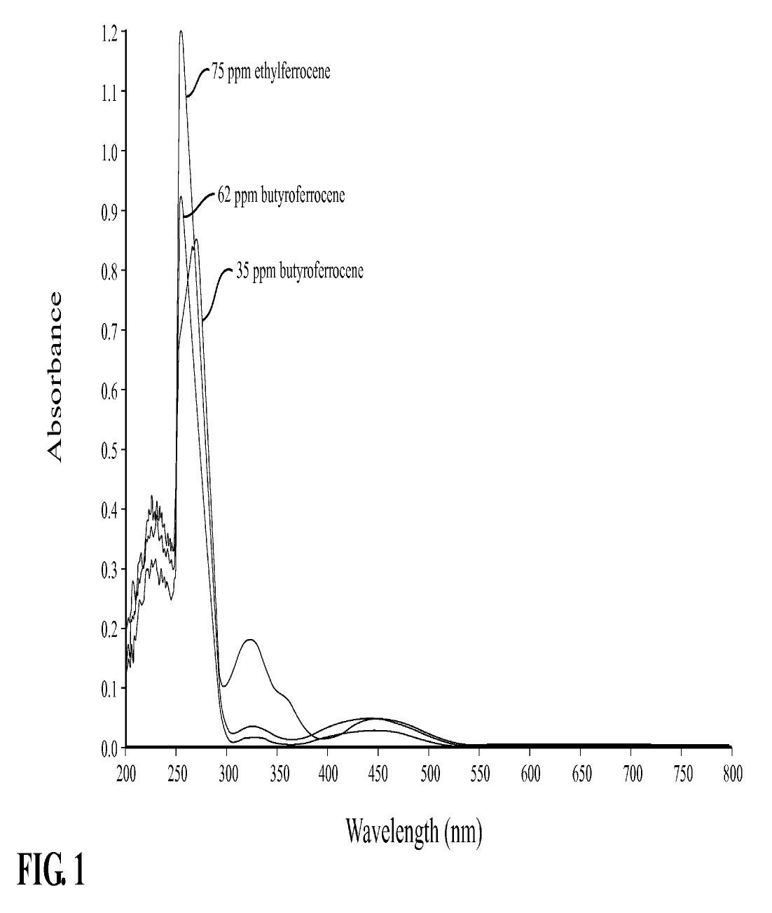

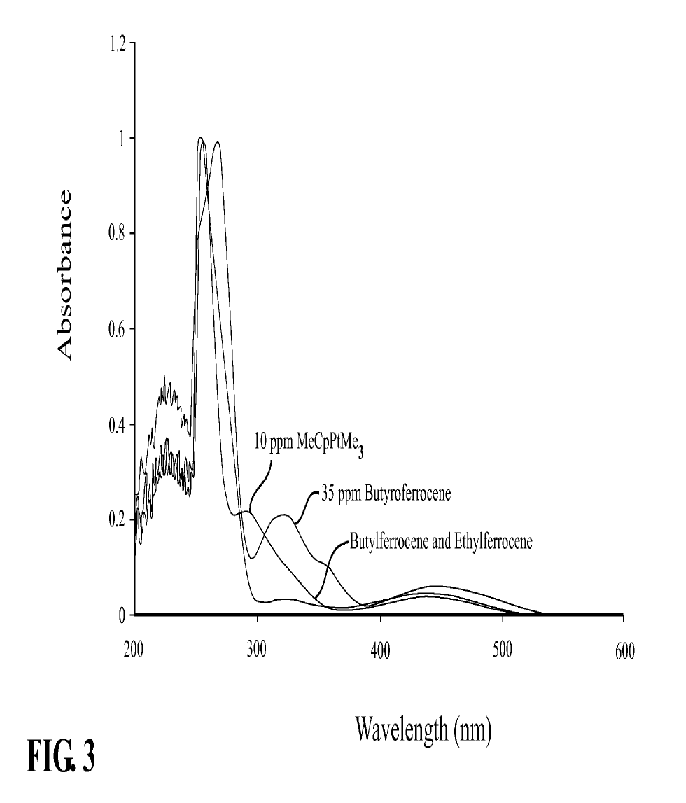

It is contemplated that the amount of UV light needed to activate the (C) UV-activated hydrosilylation catalyst may change depending on choice of catalyst. Similarly, the choice of (D) thermal stabilizer may also be made in consideration of the choice of the (C) UV-activated hydrosilylation catalyst and the amount of UV light needed for activation, for example, as shown in FIGS. 1-3. Typically, the (D) thermal stabilizer has transparency to UV light at a wavelength between about 10 and about 400 nanometers sufficient for the ultraviolet hydrosilylation reaction product to form. In other embodiments, the thermal stabilizer has transparency to UV light at a wavelength between about 50 and about 400, about 100 and about 400, about 150 and about 400, about 200 and about 400, about 250 and about 400, about 300 and about 400, or about 350 and about 400, nanometers sufficient for the ultraviolet hydrosilylation reaction product to form. In various embodiments, the (D) thermal stabilizer has less than 2, 1.9, 1.8, 1.7, 1.6, 1.5, 1.4, 1.3, 1.2, 1.1, 1.0, 0.9, 0.8, 0.7, 0.6, 0.5, 0.4, 0.3, 0.2, or 0.1, units of UV absorbance at one or more wavelengths described above, e.g. shown in one or more of FIGS. 1-3. These units of UV absorbance may be determined using any ASTM or similar type of test and any type of spectrophotometer in the art.

In one embodiment, the (D) thermal stabilizer is further defined as a ferrocene. Typically, a ferrocene includes two cyclopentadienyl rings bound on opposite sides of a central iron atom. In one embodiment, the (D) thermal stabilizer may be described as ferrocene itself, i.e., C₁₀H₁₀Fe, CAS Number: 102-54-5 One or both of the cyclopentadienyl rings may be substituted or unsubstituted. The ferrocene may be selected from the group consisting of t-butyl ferrocene, i-propyl ferrocene, N,N-dimethylaminoethyl ferrocene, n-butyl ferrocene, ethyl ferrocene, and combinations thereof. In one embodiment, the ferrocene is ethyl ferrocene. In other embodiments, the ferrocene is selected from the group consisting of, acetylferrocene, vinylferrocene, ethynylferrocene, ferrocenyl methanol, bis(eta-cyclopentadienyl)iron (III) tetrachloroferric acid (III) salt, tetracarbonyl bis(eta-cyclopentadienyl)2 iron (I), 1,1′-bis(trimethylsilyl)ferrocene, 1,1°-(dimethylphenoxysilyl)ferrocene, 1,1′-bis(dimethylethoxysilyl)ferrocene, and combinations thereof. Alternatively, one or both of the cyclopentadienyl rings may include one or more saturated or unsaturated hydrocarbon groups bonded thereto, e.g. those having from 1 to 10, 2 to 9, 3 to 8, 4 to 7, or 5 or 6, carbon atoms. Alternatively, one or both of the cyclopentadienyl rings may include one or more nitrogen containing groups (e.g. amino groups), sulfur containing groups (e.g. thiol groups), phosphorous containing groups (e.g. phosphate groups), carboxyl groups, ketones, aldehydes, alcohols, and the like. It is also contemplated that one or both of the cyclopentadienyl rings may include one or more polymerizable groups such that one or more ferrocene molecules may be polymerizable together or polymerized together, e.g. to form oligomers and/or polymers.

The (D) thermal stabilizer is present in an amount of from about 0.01 to about 30 weight percent based on a total weight of (A) and (B). It is alternatively contemplated that the (D) thermal stabilizer may be present in an amount of from about 0.05 to about 30, about 0.05 to about 5, about 0.01 to about 0.1, about 0.1 to about 5, about 0.1 to about 1, about 0.05 to about 1, about 1 to about 5, about 2 to about 4, about 2 to about 3, about 5 to about 25, about 10 to about 20, or about 15 to about 20, weight percent based on a total weight of (A) and (B).

### (E) Silicone Fluid:

The gel may also be formed utilizing (E) a silicone fluid. The (E) silicone fluid may be alternatively described as only one of, or as a mixture of, a functional silicone fluid and/or a non-functional silicone fluid. In one embodiment, (E) is further defined as a polydimethylsiloxane, which is not functional. In another embodiment, (E) is further defined as a vinyl functional polydimethylsiloxane. The terminology “functional silicone fluid” typically describes that the fluid is functionalized to react in a hydrosilylation reaction, i.e., include unsaturated groups and/or Si-H groups. However, it is contemplated that the fluid may include one or more additional functional groups in addition to, or in the absence of, one or more unsaturated and/or Si-H groups. In various non-limiting embodiments, (E) is as described in one or more of U.S. Pat. Nos. 6,020,409; 4,374,967; and/or 6,001,918, each of which is expressly incorporated herein by reference. (E) is not particularly limited to any structure or viscosity.

(E) may or may not participate as a reactant with (A) and (B) in a hydrosilylation reaction. In one embodiment, (E) is a functional silicone fluid and reacts with (A) and/or (B) in the presence of (C) and (D). Said differently, the hydrosilylation reaction product may be further defined as the hydrosilylation reaction product of (A), (B), and (E) the functional silicone fluid wherein (A), (B), and (E) react via hydrosilylation in the presence of (C) and (D). In another embodiment, A) and (B) react via hydrosilylation in the presence of (C), (D), and (E) a non-functional silicone fluid.

### Optional Additives:

One or more of (A)-(E) may be combined together to form a mixture and the mixture may further react with remaining components of (A)-(E) to form the gel, with (E) being an optional component in either the mixture or as a remaining component. In other words, any combination of one or more (A)-(E) may react with any other combination of one or more of (A)-(E) so long as the gel is formed. The mixture, or any one or more of the remaining component of (A)-(E) may be independently combined with one or more additives including, but not limited to, inhibitors, spacers, electricity and/or heat conducting and/or non-conducting fillers, reinforcing and/or non-reinforcing fillers, filler treating agents, adhesion promoters, solvents or diluents, surfactants, flux agents, acid acceptors, hydrosilylation stabilizers, stabilizers such as heat stabilizers and/or UV stabilizers, UV sensitizers, and the like. Examples of the aforementioned additives are described in U.S. Prov. App. Ser. No. 61/436,214, filed on Jan. 26, 2011, which is expressly incorporated herein by reference but does not limit the instant disclosure. It is also contemplated that one of more of (A)-(C) or any one or more of the additives may be as described in PCT/US2009/039588, which is also expressly incorporated herein by reference. It is also contemplated that the gel and/or the electronic article of this disclosure may be free of one or more of any of the aforementioned additives.

### Gel:

The hardness is measured and calculated as described below using a TA-23 probe. The gel typically has a hardness of less than about 1000 grams as measured after heat ageing for 500 hours at 225° C. or 250° C. In one embodiment, the gel has a hardness of less than about 1500 grams as measured after heat ageing for 1000 hours at 225° C. In one alternative embodiment, the gel has a hardness of less than about 1500 grams as measured after heat ageing for 500 hours at 225° C. In other alternative embodiments, the gel has a hardness of less than 1400, 1300, 1200, 1100, 1000, 900, 800, 700, 600, 500, 400, 300, 200, 100, 90, 80, 70, 60, 50, 40, 30, or 20, grams as measured after heat ageing at 225° C. or 250° C. for 250 hours, for 500 hours, or for 1000 hours. In various embodiments, the gel has a hardness of less than 105, less than 100, less than 95, less than 90, less than 85, less than 80, less than 75, less than 70, less than 65, less than 60, less than 55, less than 50, less than 45, less than 40, less than 35, less than 30, less than 25, or less than 20, grams, as measured after heat ageing for 500 hours at 225° C. It is also contemplated that the hardness of the gel can be measured using different, but similar, heat ageing times and temperatures. The hardness of the gel may or may not initially decrease after heat ageing. It is contemplated that the hardness of the gel may remain lower after heat ageing than before or may eventually increase to a hardness that is greater, but typically only after long periods of time. In various embodiments, these hardness values vary by ±5%, ±10%, ±15%, ±20%, ±25%, ±30%, etc.

The hardness is calculated as the weight required to insert a TA-23 probe into the gel to a depth of 3 mm More specifically, the method used to calculate hardness utilizes a Universal TA.XT2 Texture Analyzer (commercially available from Texture Technologies Corp., of Scaresdale, N.Y.) or its equivalent and a TA-23 (0.5 inch round) probe. The Texture Analyzer has a force capacity of 55 lbs and moves the probe at a speed of 1.0 mm/s The Trigger Value is 5 grams, the Option is set to repeat until count and to set count to 5, the Test Output is Peak, the force is measured in compression, and the container is a 4 oz wide-mouth, round glass bottle. All measurements are made at 25° C. ±5° C. and 50% ±4% relative humidity. Even more specifically, samples of the gel are prepared, reacted, and stabilized at room temperature (25° C. ±5° C.) for at least 0.5 hours, for 2 to 3 hours, or until a stable hardness is reached. The sample is then positioned on the test bed directly under the probe. The Universal TA.XT2 Texture Analyzer is then programmed with the aforementioned specific parameters according to the manufacturer's operating instructions. Five independent measurements are taken at different points on the surface of the gel. The median of the five independent measurements are reported. The test probe is wiped clean with a soft paper towel after each measurement is taken. The repeatability of the value reported (i.e., the maximum difference between two independent results) should not exceed 6 g at a 95% confidence level. Typically, the thickness of the sample is sufficient to ensure that when the sample is compressed, the force measurement is not influenced by the bottom of the bottle or the surface of the test bed. When performing measurements, the probe is typically not within 0.5 inch of the side of the sample.

The combination of (A) to (D), and optionally (E), before reaction to form the gel, typically has a viscosity less than about 100,000, 75,000, 50,000, 25,000, or 10,000, cps measured at 25° C. using a Brookfield DV-II+cone and plate viscometer with spindle CP-52 at 50 rpm. In various embodiments, the combination of (A) to (D), (and optionally (E)) before reaction to form the gel, has a viscosity of less than 9,500, less than 9,000, less than 8,500, less than 8,000, less than 7,500, less than 7,000, less than 6,500, less than 6,000, less than 5,500, less than 5,000, less than 4,500, less than 4,000, less than 3,500, less than 3,000, less than 2,500, less than 2,000, less than 1,500, less than 1,000, less than 500, less than 400, less than 300, less than 200, less than 100, less than 90, less than 80, less than 70, less than 60, less than 50, less than 40, less than 30, less than 20, or less than 10, cps measured at 25° C. using a Brookfield DV-II+ cone and plate viscometer with spindle CP-52 at 50 rpm.

The gel is also typically non-opaque to both visible and/or UV light. Said differently, the gel may be transparent or see-through to both visible and/or UV light, as determined visually and/or through use of a UV/Vis spectrophotometer. Alternatively, the gel may have a visible and/or UV light transmittance of greater than 50, 55, 60, 65, 70, 75, 80, 85, 95, 95, or 99, percent, as determined using a UV/Vis spectrophotometer at one or more UV or visible wavelengths. It is contemplated that the gel may be colored yet still remain transparent or see-through. Typically, the (D) thermal stabilizer chosen for use in this disclosure should not have UV absorption spectrum that overlaps with the UV absorption spectrum of the (C) UV-activated hydrosilylation catalyst to such a degree that the (D) thermal stabilizer absorbs or blocks the needed amount of UV light from reaching and activating the (C) catalyst.

### Method of Forming the Gel:

This disclosure also provides a method of forming the gel. The method typically includes the steps of providing (A), providing (B), providing (C), providing (D), and optionally providing (E). Each may be provided independently or in conjunction with one or more of the others. The method may also include the steps of combining one or more of (A)-(D) (and optionally (E)) together to form a mixture. The method also includes the step of applying ultraviolet light to the mixture (e.g. in an amount sufficient) to effect a hydrosilylation reaction of (A) and (B) in the presence of (C) and (D) to form the gel. The method may also include the steps of reacting or partially reacting (e.g. partially curing), via hydrosilylation, (A) and (B), in the presence of (C) and (D) and optionally (E). It is also contemplated that (A) and (B) may react with or in the presence of one of more of the aforementioned additives or other monomers or polymers described above or in any one of the documents incorporated herein by reference.

In one embodiment, the method includes the step of combining (A), (B), (C), (D), and (E) to effect a hydrosilylation reaction of (A) and (B) in the presence of (C), (D), and (E) to form the gel. Alternatively, (A)-(D) may be combined with (E). It is contemplated that any and all combinations of steps of adding each of (A)-(E) both independently and/or in conjunction with one or more of the others of (A)-(E) may be utilized in this disclosure.

Typically, (A) and (B) are present, and/or reacted, in an amount such that a ratio of silicon-bonded hydrogen atoms to silicon-bonded alkenyl groups is less than about 1.3:1. Alternatively, the ratio may be about 1:1 or less than about 1:1. In still other embodiments, the ratio is less than 0.9:1, 0.8:1, 0.7:1, 0.6:1, or 0.5:1.

### Electronic Article:

The instant disclosure also provides an electronic article (hereinafter referred to as an “article.”) The article may be a power electronic article. The article includes an electronic component and the gel disposed on the electronic component. The gel may be disposed on the electronic component such that the gel encapsulates, either partially or completely, the electronic component. Alternatively, the electronic article may include the electronic component and a first layer. The gel may be sandwiched between the electronic component and the first layer, may be disposed on and in direct contact with the first layer, and/or on and in direct contact with the electronic component. If the gel is disposed on and in direct contact with the first layer, the gel may still be disposed on the electronic component but may include one or more layers or structures between the gel and the electronic component. The gel may be disposed on the electronic component as a flat member, a hemispherical nubbin, a convex member, a pyramid, and/or a cone. The electronic component may be further defined as a chip, such as a silicon chip or a silicon carbide chip, one or more wires, one or more sensors, one or more electrodes, and the like.

The electronic article is not particularly limited and may be further defined as an insulated gate bipolar transistor (IGBT), a rectifier such as a Schottky diode, a PiN diode, a merged PiN/Schottky (MPS) rectifier and Junction barrier diode, a bipolar junction transistors (BJTs), a thyristor, a metal oxide field effect transistor (MOSFET), a high electron mobility transistor (HEMT), a static induction transistors (SIT), a power transistor, and the like. The electronic article can alternatively be further defined as power modules including one of more of the aforementioned devices for power converters, inverters, boosters, traction controls, industrial motor controls, power distribution and transportation systems. The electronic article can alternatively be further defined as including one or more of the aforementioned devices.

In addition, the first layer is not particularly limited and may be further independently defined as a semiconductor, a dielectric, metal, plastic, carbon fiber mesh, metal foil, a perforated metal foil (mesh), a filled or unfilled plastic film (such as a polyamide sheet, a polyimide sheet, polyethylene naphthalate sheet, a polyethylene terephthalate polyester sheet, a polysulfone sheet, a polyether imide sheet, or a polyphenylene sulfide sheet), or a woven or nonwoven substrate (such as fiberglass cloth, fiberglass mesh, or aramid paper). Alternatively, the first layer may be further defined as a semiconductor and/or dielectric film.

The disclosure also provides a method of forming the electronic article. The method may include one or more of the aforementioned steps of forming the gel, the step of providing the gel, and/or the step of providing the electronic component. Typically, the method includes the step of applying (A)-(D) and optionally (E) onto the electronic component and reacting (A) and (B) in the presence of (C) and (D) and optionally (E) to form the gel on the electronic component under the condition sufficient to form the gel without damaging the component. Alternatively, the gel may be formed apart from the electronic component and subsequently be disposed on the electronic component.

### EXAMPLES

A series of gels (Gels 1-4) are formed using an (A) organopolysiloxane, a (B) cross-linker, a (C) UV-activated hydrosilylation catalyst, and a (D) thermal stabilizer and are non-limiting examples of this disclosure. None of the Gels 1-4 are formed using any (E) silicone fluid.

A comparative gel (Comparative Gel 1) is also contemplated but does not include the (C) UV-activated hydrosilylation catalyst of this disclosure or the (D) thermal stabilizer of this disclosure.

Comparative Gels 2A and 2B are also contemplated and each includes the (C) UV-activated hydrosilylation catalyst of this disclosure but neither includes the (D) thermal stabilizer.

Comparative Gel 2A includes iron acetylacetonate (Fe(acac)) instead of the (D) thermal stabilizer.

Comparative Gel 2B includes copper phthalocyanine instead of the (D) thermal stabilizer.

Comparative Gel 3 is also contemplated and includes the (D) thermal stabilizer of this disclosure but does not include the (C) UV-activated hydrosilylation catalyst.

Comparative Gel 4 is also formed and includes the (C) UV-activated hydrosilylation catalyst but does not include (D) thermal stabilizer of this disclosure.

The compositions used to attempt to form each of the Gels and the results of the aforementioned evaluations are set forth in Table 1 below. More specifically, equal weight parts of Part A and Part B are mixed and de-aired to form a mixture. The mixture is then poured into an aluminum cup and exposed to UV light at room temperature for 5 seconds at 500 mJ/cm² to form the Gels. After the gels have formed and have reached a plateau in hardness (˜2 to 3 hours), their hardness is determined pursuant to the methods described in detail above. Then, a first series of samples of the Gels are heat aged and again evaluated for hardness after heat ageing for 500 hours at 225° C. A second series of samples of the Gels are heat aged and again evaluated for hardness after heat ageing for 500 hours at 225° C.

In Table 1, all weight percentages set forth in Part A are based on a total weight of Part A. All weight percentages set forth in Part B are based on a total weight of Part B. The values for gel hardness set forth in all tests below represent the average (mean) of 5 independent measurements of the respective Gel. The gels are also evaluated to determine gel time in seconds. Gel time is determined visually by tipping the aluminum cup after exposure to the UV light. Once the developing gel no longer flows in the cup, the time is determined to be the gel time.

TABLE 1

| | Gel 1 | Gel 2 | Gel 3 | Gel 4 |
|---|---|---|---|---|
| Part A | | | | |
| (A) Organopolysiloxane | ~99.97 wt % | ~99.89 wt % | ~99.79 wt % | ~99.79 wt % |
| (C) UV-activated | ~0.01 wt % | ~0.01 wt % | ~0.01 wt % | ~0.01 wt % |
| hydrosilylation catalyst | | | | |
| (D) Thermal Stabilizer | ~0.02 wt % | ~0.1 wt % | ~0.2 wt % | ~0.2 wt % |
| | | | | (butyroferrocene) |
| Fe(acac) | — | — | — | — |
| Copper Phthalocyanine | — | — | — | — |
| Part B | | | | |
| (A) Organopolysiloxane | ~92.5 wt % | ~92.5 wt % | ~92.5 wt % | ~92.5 wt % |
| (B) Cross-Linker | ~7.5 wt % | ~7.5 wt % | ~7.5 wt % | ~7.5 wt % |
| Gel Time (s) | 140 | 160 | 190 | Did Not Gel |
| Initial Hardness (g) | ~170 | ~165 | ~142 | N/A |
| Prior to Heat Ageing | | | | |
| Final Hardness (g) | ~372 | ~547 | ~736 | N/A |
| After Heat Ageing | | | | |
| For 500 hours at 225° C. | | | | |
| Final Hardness (g) | ~1885 | ~1581 | ~1587 | N/A |
| After Heat Ageing | | | | |
| For 500 hours at 250° C. | | | | |

| | Comp. | Comp. | Comp. | Comp. | Comp. |
|---|---|---|---|---|---|
| | Gel 1 | Gel 2A | Gel 2B | Gel 3 | Gel 4 |
| Part A | | | | | |
| (A) | ~100 wt % | ~98.99 wt % | ~98.99 wt % | ~99.8 wt % | ~99.99 wt % |
| Organopolysiloxane | | | | | |
| (C) UV-activated | — | ~0.01 wt % | ~0.01 wt % | — | ~0.01 wt % |
| hydrosilylation | | | | | |
| catalyst | | | | | |
| (D) Thermal Stabilizer | — | — | — | ~0.2 wt % | — |
| Fe(acac) | — | ~1 wt % | — | — | — |
| Copper | — | — | ~1 wt % | — | — |
| Phthalocyanine | | | | | |
| Part B | | | | | |
| (A) | ~92.5 wt % | ~92.5 wt % | ~92.5 wt % | ~92.5 wt % | ~92.5 wt % |
| Organopolysiloxane | | | | | |
| (B) Cross-Linker | ~7.5 wt % | ~7.5 wt % | ~7.5 wt % | ~7.5 wt % | ~7.5 wt % |
| Gel Time (s) | Did Not | Did Not Gel | Did Not | Did Not | 130 |
| | Gel | | Gel | Gel | |
| Initial Hardness (g) | N/A | N/A | N/A | N/A | ~41 |
| Prior to Heat Ageing | | | | | |
| Final Hardness (g) | N/A | N/A | N/A | N/A | ~2335 |
| After Heat Ageing | | | | | |
| For 500 hours at | | | | | |
| 225° C. | | | | | |
| Final Hardness (g) | N/A | N/A | N/A | N/A | N/A - |
| After Heat Ageing | | | | | Cracked |
| For 500 hours at | | | | | |
| 250° C. | | | | | |

The (A) Organopolysiloxane is a dimethylvinylsiloxy terminated polydimethylsiloxane.

The (B) Cross-Linker is a trimethylsiloxy terminated dimethylmethylhydrogen siloxane.

The (C) UV-activated hydrosilylation catalyst is MeCpPtMe₃.

The (D) Thermal Stabilizer is ethyl ferrocene for all Gels except Gel 4 which utilizes butyroferrocene.

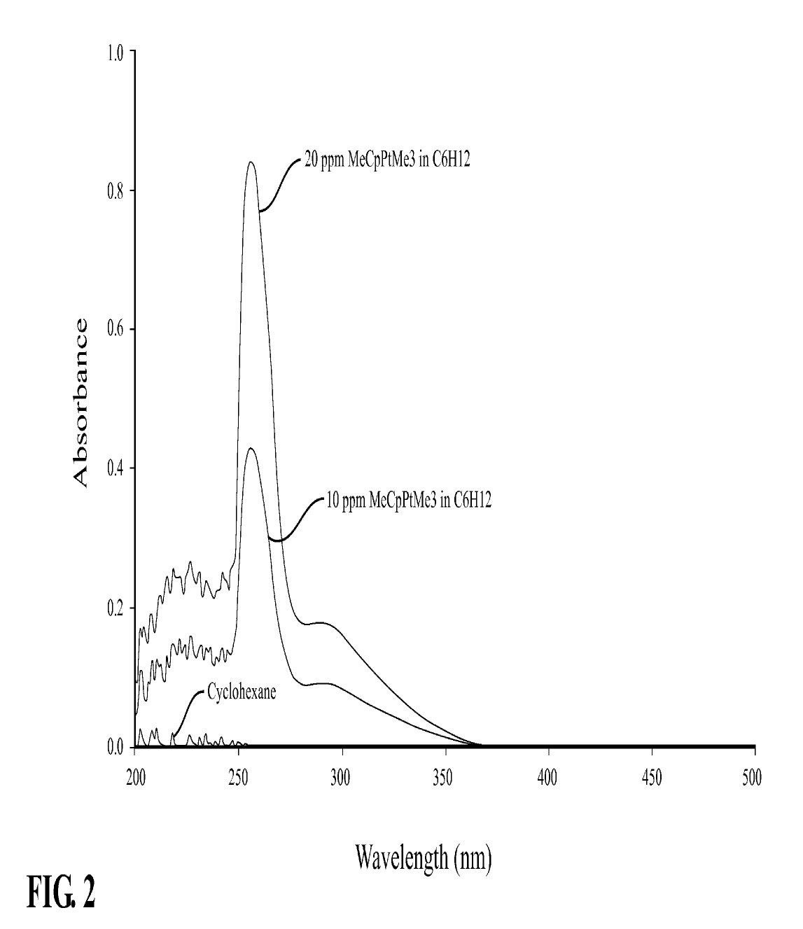

The data above clearly establishes that the Gels 1-3 of this disclosure outperform the Comparative Gels. Gel 4 does not form because the butyroferrocene absorbs a sufficient amount of UV light across the same general wavelengths at which the particular catalyst (MeCpPtMe₃) absorbs UV light, as shown in FIGS. 1 and 2. It is theorized that the butyroferrocene absorbs enough UV light at these wavelengths such that MeCpPtMe₃ is not sufficiently activated. For this reason, (A) and (B) do not undergo any appreciable hydrosilylation reaction. However, the butyroferrocene may function as well or better than other ferrocenes when utilized in conjunction with a different catalyst due to differing UV absorption spectra.

Comparative Gel 1 does not form because there is no (C) UV-activated hydrosilylation catalyst present. As such, no appreciable hydrosilylation reaction occurs.

Comparative Gels 2A and 2B do not form because the Fe(acac) and Copper Phthalocyanine block a substantial amount of UV light from penetrating the combination of Parts A and B such that the (C) UV-activated hydrosilylation catalyst is not activated. Just as above, no appreciable hydrosilylation reaction occurs.

Comparative Gel 3 does not form because there is no (C) UV-activated hydrosilylation catalyst present. As such, no appreciable hydrosilylation reaction occurs.

If the catalyst is not activated with UV light or is not present, the gels do not form. Said differently, without UV light, the (C) UV-activated hydrosilylation catalyst is not activated and no appreciable hydrosilylation reaction occurs. Comparative Gel 4 forms but is entirely unsatisfactory because it cracks after heat ageing. Comparative Gel 4 cracks because it does not include any of the (D) thermal stabilizer.

The (C) UV-activated hydrosilylation catalyst allows the gel to form (i.e., allows (A) and (B) to react) without the use of heat which reduces production times, costs, and complexities. The (D) thermal stabilizer in Gels 1-3 does not prevent the UV light from penetrating the gel and simultaneously allows gel to maintain low modulus (i.e., low hardness and viscosity) properties even after extensive heat ageing. Maintenance of the low modulus properties allows the gel to be utilized in an electronic article with minimal impact on electrodes and electrical wires after heat ageing.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

1. A gel that has improved thermal stability and that is an ultraviolet hydrosilylation reaction product of:
(A) an organopolysiloxane having an average of at least 0.1 silicon-bonded alkenyl group per molecule; and
(B) a cross-linker having an average of at least 2 silicon-bonded hydrogen atoms per molecule;
wherein (A) and (B) react via hydrosilylation in the presence of;
(C) a UV-activated hydrosilylation catalyst comprising at least one of platinum, rhodium, ruthenium, palladium, osmium, and iridium, and
(D) a thermal stabilizer present in an amount of from about 0.01 to about 30 weight percent based on a total weight of (A) and (B) and having transparency to UV light sufficient for said ultraviolet hydrosilylation reaction product to form.

2. A gel according to claim 1 wherein said thermal stabilizer has transparency to UV light at a wavelength between about 150 and about 400 nanometers sufficient for the ultraviolet hydrosilylation reaction product to form.

3. A gel according to claim 2 wherein the wavelength is between about 300 and about 400 nanometers.

4. A gel according to claim 1 wherein said thermal stabilizer is a ferrocene.

5. A gel according to claim 4 wherein said ferrocene is selected from the group consisting of t-butyl ferrocene, i-propyl ferrocene, N,N-dimethylaminoethyl ferrocene, n-butyl ferrocene, ethyl ferrocene, and combinations thereof.

6. A gel according to claim 4 wherein said ferrocene is ethyl ferrocene.

7. A gel according to claim 1 having a hardness of less than about 1000 grams as measured after heat ageing for 500 hours at 225° C. that is calculated as a weight required to insert a TA-23 probe into said gel to a depth of 3 mm.

8. A gel according to claim 1 wherein said (C) UV-activated hydrosilylation catalyst is a platinum catalyst.

9. A gel according to claim 8 wherein said platinum catalyst is present in an amount of from 0.1 to 1000 parts by weight per one million parts by weight of (A), (B), and (C).

10. A gel according to claim 8 wherein said platinum catalyst is methylcyclopentadienyl trimethylplatinum.

11. A gel according to claim 1 wherein said (D) thermal stabilizer is present in an amount of from 0.01 to 0.1 weight percent based on a total weight of (A) and (B).

12. A gel according to claim 1 wherein (A) and (B) react via hydrosilylation in the presence of (C), (D), and (E) a non-functional silicone fluid.

13. A gel according to claim 1 wherein said ultraviolet hydrosilylation reaction product is further defined as an ultraviolet hydrosilylation reaction product of (A), (B), and (E) a functional silicone fluid and wherein (A), (B), and (E) react via hydrosilylation in the presence of (C) and (D).

14. A method of forming a gel that has improved thermal stability and that is the ultraviolet hydrosilylation reaction product of (A) an organopolysiloxane having an average of at least 0.1 silicon-bonded alkenyl group per molecule and (B) a cross-linker having an average of at least 2 silicon-bonded hydrogen atoms per molecule, wherein (A) and (B) react via hydrosilylation in the presence of (C) a UV-activated hydrosilylation catalyst comprising at least one of platinum, rhodium, ruthenium, palladium, osmium, and iridium and (D) a thermal stabilizer present in an amount of from about 0.01 to about 30 weight percent based on a total weight of (A) and (B) and having transparency to UV light sufficient for the ultraviolet hydrosilylation reaction product to form, said method comprising the steps of:
(I) combining (A), (B), (C), and (D) to form a mixture; and
(II) applying ultraviolet light to the mixture to effect a hydrosilylation reaction of (A) and (B) in the presence of (C) and (D) to form the gel.

15-21. (canceled)

22. A method according to claim 14 wherein (A) and (B) react via hydrosilylation in the presence of (C), (D), and (E) a non-functional silicone fluid.

23. A method according to claim 14 wherein the ultraviolet hydrosilylation reaction product is further defined as an ultraviolet hydrosilylation reaction product of (A), (B), and (E) a functional silicone fluid and wherein (A), (B), and (E) react via hydrosilylation in the presence of (C) and (D).

24. An electronic article comprising an electronic component and a gel having improved thermal stability, wherein said gel is disposed on said electronic component and is the ultraviolet hydrosilylation reaction product of:
(A) an organopolysiloxane having an average of at least 0.1 silicon-bonded alkenyl group per molecule; and
(B) a cross-linker having an average of at least 2 silicon-bonded hydrogen atoms per molecule;
wherein (A) and (B) react via hydrosilylation in the presence of;
(C) a UV-activated hydrosilylation catalyst comprising at least one of platinum, rhodium, ruthenium, palladium, osmium, and iridium, and
(D) a thermal stabilizer present in an amount of from about 0.01 to about 30 weight percent based on a total weight of (A) and (B) and having transparency to UV light sufficient for the ultraviolet hydrosilylation reaction product to form.

25-34. (canceled)

35. An electronic article according to claim 24 wherein said electronic component is further defined as a chip, wherein said gel encapsulates said chip, and wherein said electronic article is further defined as an insulated bipolar transistor.
